(19) United States
(12) Patent Application Publication
(10) Pub. No.: US 2025/0157894 A1
(43) Pub. Date: May 15, 2025

(54) BATTERY PROTECTION PACKAGE HAVING CO-PACKED TRANSISTORS AND INTEGRATED CIRCUIT AND METHOD OF MAKING THE SAME

(71) Applicant: ALPHA AND OMEGA SEMICONDUCTOR INTERNATIONAL LP, TORONTO (CA)

(72) Inventors: Yan Xun Xue, Los Gatos, CA (US); Jian Yin, San Ramon, CA (US); Long-Ching Wang, Cupertino, CA (US); Sitthipong Angkititrakul, Dublin, CA (US); Xiaobin Wang, San Jose, CA (US); Bo Chen, Shanghai (CN)

(73) Assignee: ALPHA AND OMEGA SEMICONDUCTOR INTERNATIONAL LP, TORONTO, ON (CA)

(21) Appl. No.: 18/758,522

(22) Filed: Jun. 28, 2024

Related U.S. Application Data
(63) Continuation-in-part of application No. 18/509,168, filed on Nov. 14, 2023.

(51) Int. Cl. H01L 23/495; H01L 23/00; H01L 23/31; H01L 25/00; H01L 25/065; H01L 29/772

(52) U.S. Cl. CPC H01L 23/49541; H01L 25/0652; H01L 25/50; H01L 23/3107; H01L 24/32; H01L 24/33; H01L 24/48; H01L 24/73; H01L 24/92; H01L 2224/32245; H01L 2224/33181; H01L 2224/48245; H01L 2224/73265; H01L 2224/92247; H10D 30/00

(57) ABSTRACT

A semiconductor package comprises a lead frame, a first field-effect transistor (FET), a second FET, an integrated circuit (IC), a plurality of bond wires, and a molding encapsulation. The lead frame comprises a first die paddle and a second die paddle. The first FET is flipped and attached to the first die paddle. The second FET is flipped and attached to the second die paddle. A method comprises the steps of providing a lead frame comprising a first die paddle and a second die paddle; applying a first adhesive layer; mounting a first FET and a second FET; applying a second adhesive layer; mounting an IC; applying bonding wires; forming a molding encapsulation; and applying a singulation process so as to form a plurality of semiconductor packages.

### CROSS-REFERENCE TO RELATED APPLICATIONS

This patent application is a Continuation-in-part application of a pending application Ser. No. 18/509,168 filed on Nov. 14, 2023. The entire Disclosure made in the pending application Ser. No. 18/509,168 is hereby incorporated by reference.

### FIELD OF THE INVENTION

This invention relates generally to a semiconductor package and a method of making the same. More particularly, the present invention relates to the semiconductor package having co-packed transistors and an integrated circuit (IC) and the method of making the same.

### BACKGROUND OF THE INVENTION

More and more batteries are integrated into modern devices. Overcharging a battery may lead to dangerous conditions. Therefore, battery protection modules are also integrated into modern devices. A battery protection module includes a battery monitoring IC and two or more field-effect transistors (FETs).

A horizontal dimension of a conventional battery monitoring IC is 1.8 mm by 1.6 mm. A horizontal dimension of a conventional FET is 1.98 mm by 1.86 mm. The instant disclosure reduces the horizontal dimension of a co-packed semiconductor package, including a battery monitoring IC and two FETs, to 2.9 mm by 2 mm.

### SUMMARY OF THE INVENTION

The present invention discloses a semiconductor package comprising a lead frame, a first FET, a second FET, an IC, a plurality of bond wires, and a molding encapsulation. The lead frame comprises a first die paddle and a second die paddle. The first FET is flipped and attached to the first die paddle. The second FET is flipped and attached to the second die paddle.

A method for fabricating a semiconductor package is also disclosed. The method comprises the steps of providing a lead frame comprising a first die paddle and a second die paddle; applying a first adhesive layer; mounting a first FET and a second FET; applying a second adhesive layer; mounting an IC; applying bonding wires; forming a molding encapsulation; and applying a singulation process.

### BRIEF DESCRIPTION OF THE DRAWINGS

FIG. 1A is a top perspective view and FIG. 1B is a bottom perspective view of a semiconductor package in examples of the present disclosure.

FIG. 2 is a top perspective view of the semiconductor package of FIG. 1A, without showing the molding encapsulation, in examples of the present disclosure.

FIG. 3A is a cross-sectional plot along AA′ of FIG. 1A and FIG. 3B is a cross-sectional plot along BB′ of FIG. 1A in examples of the present disclosure.

FIG. 4 is a flowchart of a process to develop a semiconductor package in examples of the present disclosure.

FIGS. 5A, 5B, 5C, 5D, 5E, 5F, 5G, and 5H show perspective views of steps of the process of FIG. 3 to fabricate the semiconductor package in examples of the present disclosure. FIG. 5B is a layout of contact pads for the first FET and second FET formed on a common semiconductor substrate.

### DETAILED DESCRIPTION OF THE INVENTION

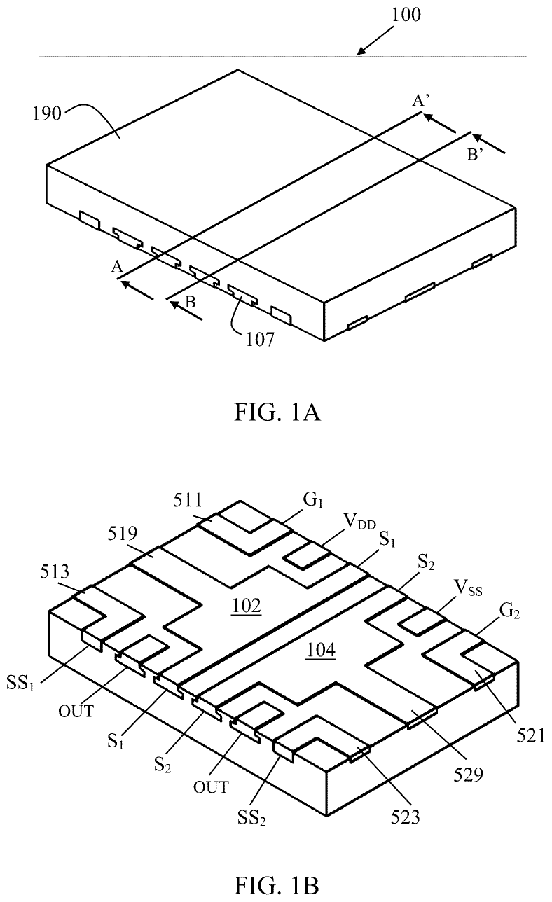

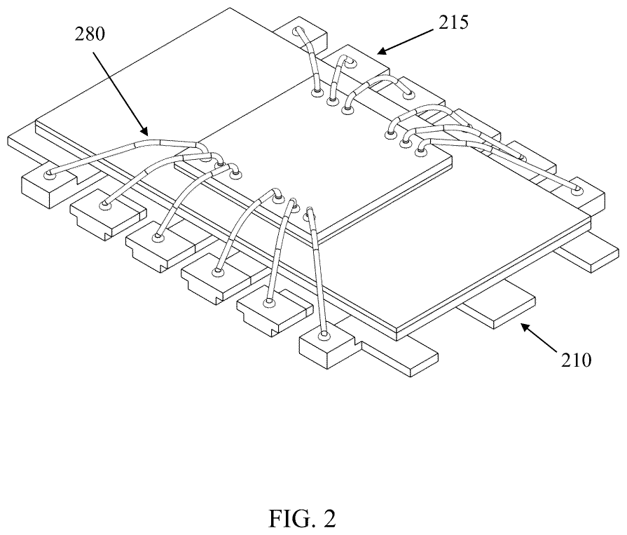

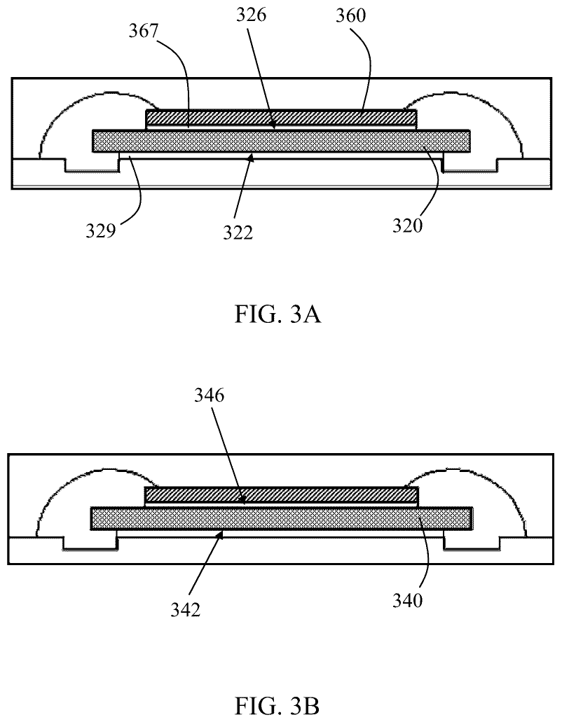

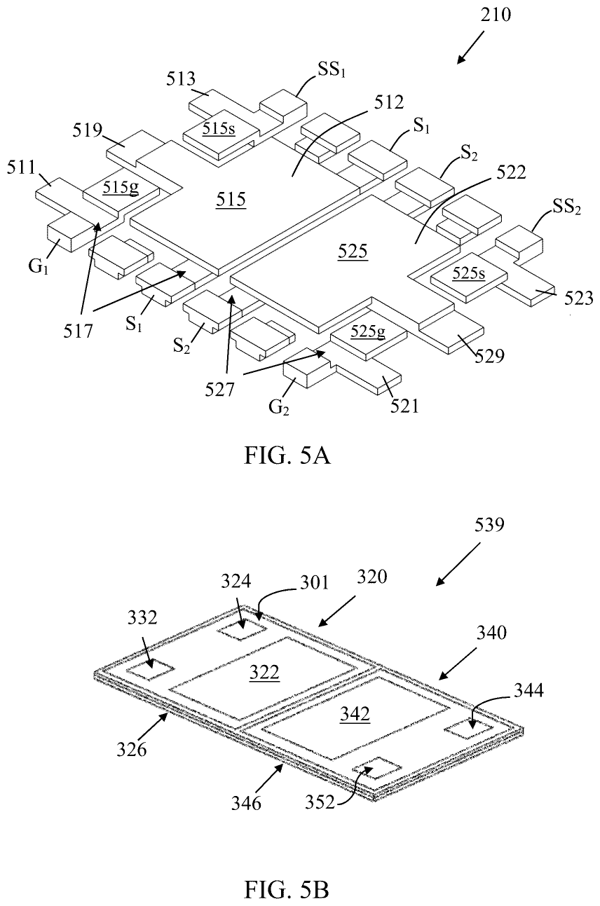

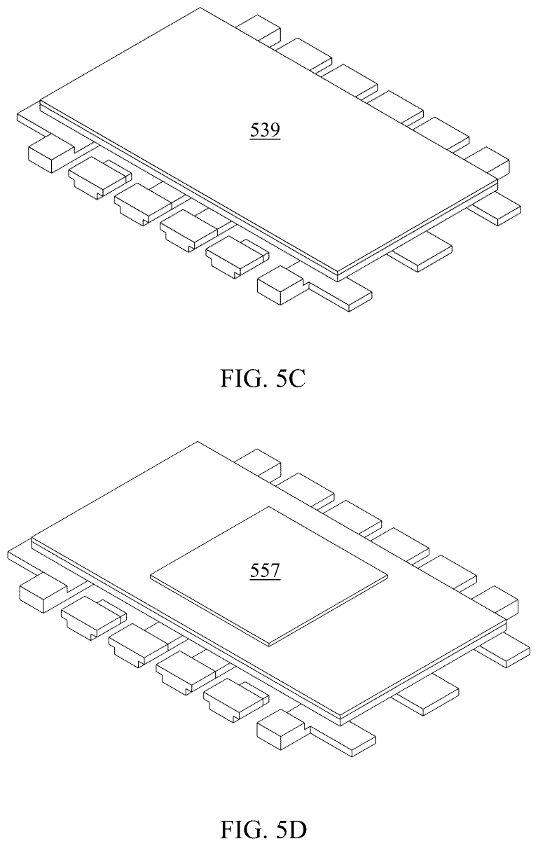

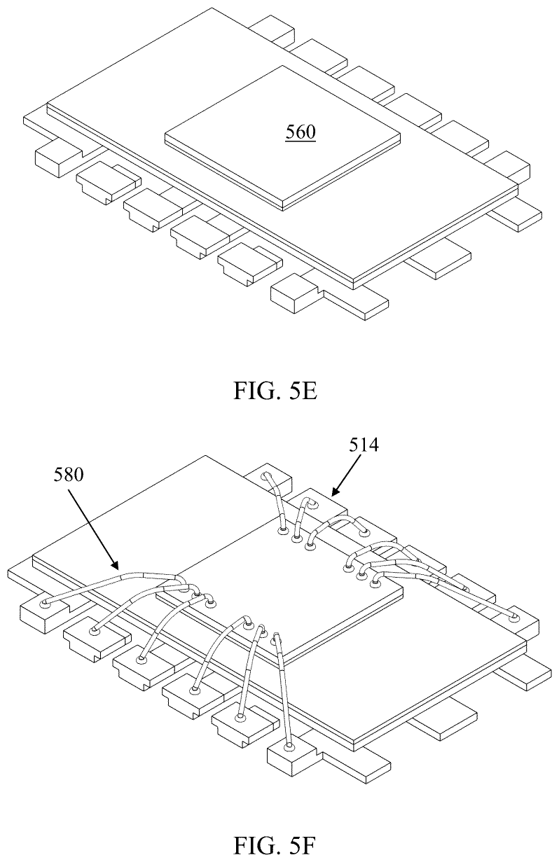

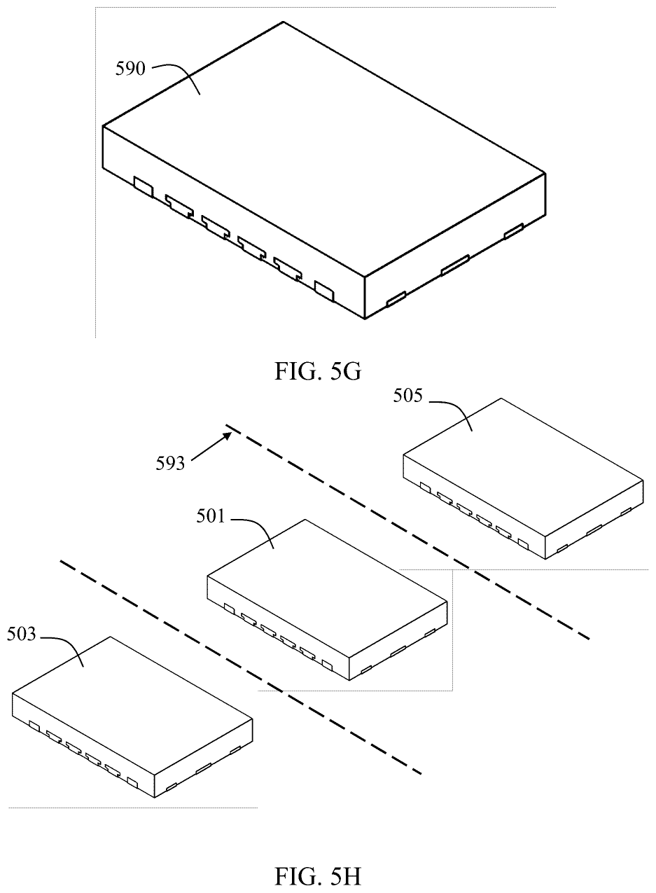

FIG. 1A is a top perspective view and FIG. 1B is a bottom perspective view of a semiconductor package 100 in examples of the present disclosure. FIG. 2 is a top perspective view of the semiconductor package 100 of FIG. 1A, without showing the molding encapsulation, in examples of the present disclosure. FIG. 3A is a cross-sectional plot along AA′ of FIG. 1A and FIG. 3B is a cross-sectional plot along BB′ of FIG. 1A in examples of the present disclosure. The semiconductor package 100 comprises a lead frame 210 of FIG. 2, a first FET 320 of FIG. 3A, a second FET 340 of FIG. 3B, an IC 360 of FIG. 3A, a plurality of bond wires 280 of FIG. 2, and a molding encapsulation 190 of FIG. 1A. In examples of the present disclosure, the first FET 320 and the second FET 340 are included in a same die 539 of FIG. 5B.

The lead frame 210 has a substantial rectangular shape and comprises a first die paddle 512 of FIG. 5A on a first end and a second die paddle 522 of FIG. 5A on a second end opposite the first end in side by side configuration. The first FET 320 is flipped with front surface attached to the first die paddle 512 by a conductive adhesive layer 329 of FIG. 3A. The first FET 320 comprises a source electrode 322 and a gate electrode 324 on a front surface of the first FET 320; and a drain electrode 326 on a back surface of the first FET 320. In examples of the present disclosure, the first FET 320 may further comprise a sense FET formed on the same semiconductor substrate 301 of FIG. 5B having a sense source electrode 332 separated from the source electrode 322 formed on the front surface, a sense gate electrically connected to the gate electrode 324, and a sense drain electrically connected to the drain electrode 326 of the first FET 320.

The second FET 340 is flipped and attached to the second die paddle 522 by a conductive adhesive layer 329. The second FET 340 comprises a source electrode 342 and a gate electrode 344 on a front surface of the second FET 340; and a drain electrode 346 on a back surface of the second FET 340. In examples of the present disclosure, the second FET 340 may further comprise a sense FET formed on the same semiconductor substrate 301 having a sense source electrode 352 separated from the source electrode 342 formed on the front surface, a sense gate electrically connected to the gate electrode 344, and a sense drain electrically connected to the drain electrode 346 of the second FET 340.

The IC 360 is positioned above the first FET 320 and the second FET 340. In examples of the present disclosure, the first FET 320 and the second FET 340 are included in a same die 539 of FIG. 5B. The IC 360 is attached to the back surface of first FET 320 and the second FET 340 by a non-conductive adhesive layer 367 of FIG. 3A. Alternatively, the first FET 320 and the second FET 340 may be formed on separate semiconductor substrates and the drain electrodes of the first FET 320 and the second FET 340 may be connected by a conductive connection member (not shown) while the IC 360 is positioned above the connection member. The lead frame 210 further comprises a plurality of leads 215 of FIG. 2. The plurality of bond wires 280 connect the IC 360 to top surfaces of the plurality of leads 215 of the lead frame 210.

In examples of the present disclosure, the molding encapsulation 190 encloses the first FET 320, the second FET 340, the IC 360, and a majority portion of the lead frame 210. In one example, a majority portion refers to a percentage larger than 50%. In examples of the present disclosure, the molding encapsulation 190 further encloses the plurality of bond wires 280.

In examples of the present disclosure, the first die paddle 512 comprises a paddle section 515 of FIG. 5A and two or more connection sections 517 of FIG. 5A. The number of the two or more connection sections 517 may vary. Each connection section of the two or more connection sections 517 is top-etched so that a thickness of each connection section of the two or more connection sections 517 is smaller than a thickness of the paddle section 515. The electrical resistance of each connection section of the two or more connection sections 517 is different from that of the paddle section 515. In one example, the thickness of each connection section of the two or more connection sections 517 is 50% of the thickness of the paddle section 515.

In examples of the present disclosure, the second die paddle 522 comprises a paddle section 525 of FIG. 5A and two or more connection sections 527 of FIG. 5A. The number of the two or more connection sections 527 may vary. Each connection section of the two or more connection sections 527 is top-etched so that a thickness of each connection section of the two or more connection sections 527 is smaller than a thickness of the paddle section 525. The electrical resistance of each connection section of the two or more connection sections 527 is different from that of the paddle section 525. In one example, the thickness of each connection section of the two or more connection sections 527 is 50% of the thickness of the paddle section 525.

In examples of the present disclosure, the IC 360 is a battery monitoring IC. The first FET 320 is a first power transistor. The second FET 340 is a second power transistor.

In examples of the present disclosure, a first source pad 102 of FIG. 1B of the first die paddle 512 is exposed from the molding encapsulation 190 and extending to first source leads S1 on two opposite sides. A second source pad 104 of FIG. 1B of the second die paddle 522 is exposed from the molding encapsulation 190 and extending to second source leads S2 on two opposite sides. A plurality of leads include a first gate lead G1 disposed on one side connected to the gate electrode 324 of the first FET 320, a first sense lead SS1 disposed on another side opposite the first gate lead G1 connected to the sense source electrode 332 of the first FET 320, a second gate lead G2 disposed on one side connected to the gate electrode 344 of the second FET 340, a second sense lead SS2 disposed on another side opposite the second gate lead G2 connected to the sense source electrode 352 of the second FET 340.

In the example of the present disclosure, the first gate lead G1 and the second gate lead G2 are located on a first side of the lead frame 210, the first sense lead and the second sense lead are located on a second side opposite the first side. In the example of the present disclosure, the first gate lead and the second gate lead are located respectively on two adjacent corners of the lead frame 210, and the first sense lead and the second sense lead are located respectively on two adjacent corners of the lead frame 210. A first gate lead tie bar 511, a first source lead tie bar 519 and a first sense source lead tie bar 513 extend vertically to a first end face and exposed through the molding at the first end face. A second gate lead tie bar 521, a second source lead tie bar 529 and a second sense source lead tie bar 523 extend vertically to a second end face and exposed through the molding at the second end face. In examples of the present disclosure, an exposed side surface 107 of FIG. 1A (exposed from the molding encapsulation 190) of an electrode lead is of a letter “T” shape.

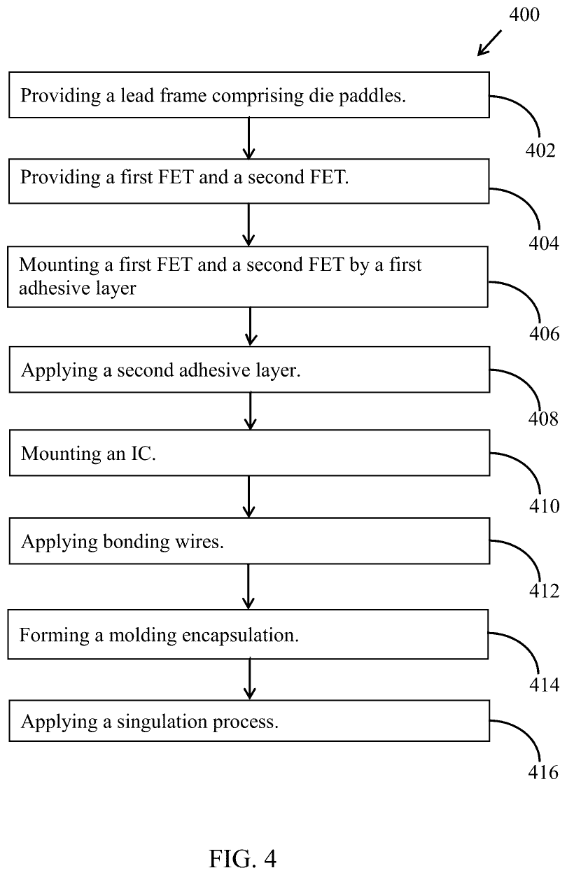

FIG. 4 is a flowchart of a process 400 to develop a semiconductor package in examples of the present disclosure. The process 400 may start from block 402. A plurality of semiconductor packages may be fabricated at the same time. In one example, FIG. 5H shows 3 semiconductor packages are fabricated at the same time. The number of semiconductor packages, fabricated at the same time, may vary. For simplicity, FIGS. 5A-5G shows the process steps for fabricating a single semiconductor package.

In block 402, referring now to FIG. 5A, a lead frame 510 is provided. The lead frame 510 comprises a first die paddle 512 and a second die paddle 522. In examples of the present disclosure, the first die paddle 512 comprises a paddle section 515, a gate section 515g, and a sense source section 515s separated from one another. The paddle section 515 is in substantial rectangular shape with the gate section 515g and the sense source section 515s disposed on two opposite cutoff corners. The gate section 515g and the sense source section 515s are bottom etched with top surfaces of the gate section 515g and the sense source section 515s coplanar to a top surface of the paddle section 515.

Two source leads S1 disposed on first and second opposite sides are connected to the paddle section 515 by two connection sections 517. A gate lead G1 disposed on the first side is connected to the gate section 515g by a connection section 517, and a sense source lead SS1 disposed on the second side is connected to the sense source section 515s by a connection section 517. A gate lead tie bar 511 connecting to the gate lead G1 through the connection section extends vertically to a first end of the lead frame. A sense source lead tie bar 513 connecting to the sense source lead SS1 through the connection section extends vertically to the first end of the lead frame. A source lead tie bar 519 between the gate lead tie bar and the sense source lead tie bar connecting to a mid-portion of the paddle section 515 between the gate section 515g and the sense source section 515s extends vertically to the first end.

The number of the connection sections 517 may vary. Each of the connection sections 517, the gate lead tie bar 511, the source lead tie bar 519 and the sense source lead tie bar 513 is top-etched so that a top surface of each connection section, the gate lead tie bar, the source lead tie bar and the sense source lead tie bar is recessed from the top surface of the paddle section 515, and a thickness of each connection section 517 is smaller than a thickness of the paddle section 515. In one example, the thickness of each connection section of the connection sections 517 is 50% of the thickness of the paddle section 515. Each of the two source leads S1, the gate lead G1, and the sense source lead SS1 has a top surface substantially coplanar to the top surface of the paddle section 515.

In examples of the present disclosure, the second die paddle 522 comprises a paddle section 525, a gate section 525g, and a sense source section 525s separated from one another. The paddle section 525 is in substantial rectangular shape with the gate section 525g and the sense source section 525s disposed on two opposite cutoff corners. The gate section 525g and the sense source section 525s are bottom etched with top surfaces of the gate section 525g and the sense source section 525s coplanar to a top surface of the paddle section 525. Two source leads S2 disposed on first and second opposite sides are connected to the paddle section 525 by two connection sections 527. A gate lead G2 disposed on the first side is connected to the gate section 525g by a connection section 527, and a sense source lead SS2 disposed on the second side is connected to the sense source section 525s by a connection section 527. A gate lead tie bar 521 connecting to the gate lead G2 through the connection section extends vertically to a second end of the lead frame. A sense source lead tie bar 523 connecting to the sense source lead SS2 through the connection section extends vertically to the second end of the lead frame. A source lead tie bar 529 between the gate lead tie bar and the sense source lead tie bar connecting to a mid-portion of the paddle section 525 between the gate section 525g and the sense source section 525s extends vertically to the first end.

The number of the connection sections 527 may vary. Each of the connection sections 527, the gate lead tie bar 521, the source lead tie bar 529 and the sense source lead tie bar 523 is top-etched so that a top surface of each connection section, the gate lead tie bar, the source lead tie bar and the sense source lead tie bar is recessed from the top surface of the paddle section 525, and a thickness of each connection section 527 is smaller than a thickness of the paddle section 525. In one example, the thickness of each connection section of the two or more connection sections 527 is 50% of the thickness of the paddle section 525. Each of the two or more source leads S2, the gate lead G2, and the sense source lead SS2 has a top surface substantially coplanar to the top surface of the paddle section 525. Block 402 may be followed by block 404.

In block 404, referring now to FIGS. 5B, a first FET 520 and a second FET 540 are provided. The first FET 520 comprises a source electrode 322 and a gate electrode 324 on a front surface of the first FET 520; and a drain electrode 326 on a back surface of the first FET 520. The first FET 520 may further comprise a sense FET formed on the same semiconductor substrate 301 having a sense source electrode 332 separated from the source electrode 322 formed on the front surface, a sense gate electrically connected to the gate electrode 324, and a sense drain electrically connected to the drain electrode 326 of the first FET 320.

The second FET 540 comprises a source electrode 342 and a gate electrode 344 on a front surface of the second FET 540; and a drain electrode 346 on a back surface of the second FET 540. The second FET 540 may further comprise a sense FET formed on the same semiconductor substrate 301 having a sense source electrode 352 separated from the source electrode 342 formed on the front surface, a sense gate electrically connected to the gate electrode 344, and a sense drain electrically connected to the drain electrode 346 of the second FET 340.

In examples of the present disclosure, the first FET 520 and the second FET 540 are formed on a same die 539 having a substantial rectangular shape. In examples of the present disclosure, the gate electrode 324 is located at a first corner of the die 539 and the sense source electrode 332 is located on a second corner of the die 539 adjacent to the first corner. The gate electrode 344 is located at a fourth corner of the die 539 adjacent the first corner and the sense source electrode 352 is located on a third corner of the die 539 adjacent to the second corner and the fourth corner.

In block 406, referring now to FIGS. 5C, die 539 is flipped and attached to lead frame 510. The front surface of the first FET 520 is flipped and is attached to the first die paddle 512 by the first adhesive layer (conductive adhesive layer 329 of FIG. 3A). The source electrode 322 of the first FET 520 is electrically connected to the paddle section 515, the gate electrode 324 of the first FET 520 is electrically connected to the gate section 515g, and the sense source electrode 332 on a front surface of the first FET 520 is electrically connected to the sense source section 515s. The front surface of the second FET 540 is flipped and is attached to the second die paddle 522 by the first adhesive layer (conductive adhesive layer 329 of FIG. 3A). The source electrode 342 of the second FET 540 is electrically connected to the paddle section 525, the gate electrode 344 of the second FET 540 is electrically connected to the gate section 525g, and the sense source electrode 352 on a front surface of the second FET 540 is electrically connected to the sense source section 525s. Block 406 may be followed by block 408.

In block 408, referring now to FIGS. 5D, a second adhesive layer 557 is applied to the first FET 520 and the second FET 540. In examples of the present disclosure, the second adhesive layer 557 is a non-conductive adhesive layer. Block 408 may be followed by block 410.

In block 410, referring now to FIG. 5E, an IC 560 is attached to the first FET 520 and the second FET 540 by the second adhesive layer 557. Block 410 may be followed by block 412.

In block 412, referring now to FIG. 5F, a plurality of bond wires 580 are applied. The lead frame 510 further comprises a plurality of leads 514. The plurality of bond wires 580 connect the IC 560 to respective top surface of the plurality of leads 514 of the lead frame 510. Block 412 may be followed by block 414.

In block 414, referring now to FIG. 5G, a molding encapsulation 590 is formed. In examples of the present disclosure, the molding encapsulation 590 encloses the first FET 520, the second FET 540, the IC 560, and a majority portion of the lead frame 510. In one example, a majority portion refers to a percentage larger than 50%. In examples of the present disclosure, the molding encapsulation 590 further encloses the plurality of bond wires 580. Block 414 may be followed by block 416.

In block 416, a singulation process 593 is applied so as to separate the semiconductor package 501 from adjacent semiconductor packages 503 and 505. In examples of the present disclosure, the IC 560 is a battery monitoring IC. The first FET 520 is a first power transistor. The second FET 540 is a second power transistor. In examples of the present disclosure, a first source pad 102 of FIG. 1B of the first die paddle 512 is exposed from the molding encapsulation 590. A second source pad 104 of FIG. 1B of the second die paddle 522 is exposed from the molding encapsulation 590. In examples of the present disclosure, an exposed side surface 107 of FIG. 1A (exposed from the molding encapsulation 590) of an electrode is of a letter “T” shape.

Those of ordinary skill in the art may recognize that modifications of the embodiments disclosed herein are possible. For example, a number of bond wires may vary. Other modifications may occur to those of ordinary skill in this art, and all such modifications are deemed to fall within the purview of the present invention, as defined by the claims.

1. A semiconductor package comprising:
a lead frame comprising
a first die paddle; and
a second die paddle;
a first field-effect transistor (FET) being flipped and attached to the first die paddle, the first FET comprising:
a source electrode and a gate electrode on a front surface of the first FET; and
a drain electrode on a back surface of the first FET;
a second FET being flipped and attached to the second die paddle, the second FET comprising:
a source electrode and a gate electrode on a front surface of the second FET; and
a drain electrode on a back surface of the second FET;
an integrated circuit (IC) positioned above the first FET and the second FET; and
a molding encapsulation enclosing the first FET, the second FET, the IC, and a majority portion of the lead frame.

2. The semiconductor package of claim 1 further comprising a semiconductor substrate;
wherein the first FET further comprises:
a sense FET formed on the semiconductor substrate;
a sense source electrode formed on the front surface of the first FET, separated from the source electrode of the first FET;
a sense gate electrically connected to the gate electrode of the first FET; and
a sense drain electrically connected to the drain electrode of the first FET.

3. The semiconductor package of claim 2, wherein the second FET further comprises:
a sense FET formed on the semiconductor substrate;
a sense source electrode formed on the front surface of the second FET, separated from the source electrode of the second FET;
a sense gate electrically connected to the gate electrode of the second FET; and
a sense drain electrically connected to the drain electrode of the second FET.

4. The semiconductor package of claim 1 wherein the first FET and the second FET are included in a same die.

5. The semiconductor package of claim 1, wherein the first die paddle comprises a paddle section and two or more connection sections;
wherein each connection section of the two or more connection sections of the first die paddle is top-etched so that a thickness of each connection section of the two or more connection sections of the first die paddle is smaller than a thickness of the paddle section of the first die paddle.

6. The semiconductor package of claim 5, wherein the first die paddle comprises the paddle section, a gate section, and a sense source section separated from one another.

7. The semiconductor package of claim 5, wherein the second die paddle comprises a paddle section and two or more connection sections;
wherein each connection section of the two or more connection sections of the second die paddle is top-etched so that a thickness of each connection section of the two or more connection sections of the second die paddle is smaller than a thickness of the paddle section of the second die paddle.

8. The semiconductor package of claim 7, wherein the second die paddle comprises the paddle section, a gate section, and a sense source section separated from one another.

9. The semiconductor package of claim 1, wherein the IC is a battery monitoring IC;
wherein the first FET is a first power transistor; and
wherein the second FET is a second power transistor.

10. The semiconductor package of claim 1, wherein a first source pad of the first die paddle is exposed from the molding encapsulation; and
wherein a second source pad of the second die paddle is exposed from the molding encapsulation.

11. A method for fabricating a semiconductor package, the method comprising the steps of:
providing a lead frame comprising
a first die paddle; and
a second die paddle;
applying a first adhesive layer to the first die paddle and the second die paddle of the lead frame;
attaching a first field-effect transistor (FET) to the first die paddle by the first adhesive layer, the first FET being flipped, the first FET comprising:
a source electrode and a gate electrode on a front surface of the first FET; and
a drain electrode on a back surface of the first FET;
attaching a second FET to the second die paddle by the first adhesive layer, the second FET being flipped, the second FET comprising:
a source electrode and a gate electrode on a front surface of the second FET; and
a drain electrode on a back surface of the second FET;
applying a second adhesive layer to the first FET and the second FET;
attaching an integrated circuit (IC) to the first FET and the second FET by the second adhesive layer;
applying a wire bonding process;
forming a molding encapsulation enclosing the first FET, the second FET, the IC, and a majority portion of the lead frame; and
applying a singulation process separating the semiconductor package from adjacent semiconductor packages.

12. The method of claim 11, wherein the first FET and the second FET are included in a same die.

13. The method of claim 11, wherein the second adhesive layer is a non-conductive adhesive layer.

14. The method of claim 11, wherein the lead frame further comprises a plurality of leads;
wherein the wire bonding process comprising:
using a plurality of bond wires connecting the IC to the plurality of leads of the lead frame; and
wherein the molding encapsulation further encloses the plurality of bond wires.

15. The method of claim 11, wherein the first die paddle comprises a paddle section and two or more connection sections;
wherein each connection section of the two or more connection sections of the first die paddle is top-etched so that a thickness of each connection section of the two or more connection sections of the first die paddle is smaller than a thickness of the paddle section of the first die paddle.

16. The method of claim 15, wherein the thickness of each connection section of the two or more connection sections of the first die paddle is 50% of the thickness of the paddle section of the first die paddle.

17. The method of claim 11, wherein the second die paddle comprises a paddle section and two or more connection sections;
wherein each connection section of the two or more connection sections of the second die paddle is top-etched so that a thickness of each connection section of the two or more connection sections of the second die paddle is smaller than a thickness of the paddle section of the second die paddle.

18. The method of claim 17, wherein the thickness of each connection section of the two or more connection sections of the second die paddle is 50% of the thickness of the paddle section of the second die paddle.

19. The method of claim 11, wherein the IC is a battery monitoring IC;
wherein the first FET is a first power transistor; and
wherein the second FET is a second power transistor.

20. The semiconductor package of claim 1, wherein a first source electrode of the first die paddle is exposed from the molding encapsulation; and
wherein a second source electrode of the second die paddle is exposed from the molding encapsulation.
